(19) United States
(12) Patent Application Publication
(10) Pub. No.: US 2026/0084571 A1
(43) Pub. Date: Mar. 26, 2026

(54) SYSTEM AND METHOD FOR DIAGNOSING AND EVALUATING A STATE OF A BATTERY

(71) Applicants: HYUNDAI MOTOR COMPANY, Seoul (KR); KIA CORPORATION, Seoul (KR)

(72) Inventors: Yo Han Baek, Hwaseong-si (KR); Bo Hyun Lee, Hwaseong-si (KR)

(73) Assignees: HYUNDAI MOTOR COMPANY, Seoul (KR); KIA CORPORATION, Seoul (KR)

(21) Appl. No.: 19/220,866

(22) Filed: May 28, 2025

(30) Foreign Application Priority Data
Sep. 26, 2024 (KR) 10-2024-0131018

(51) Int. Cl. B60L 53/66; B60L 53/10; B60L 53/62; B60L 53/67; G01R 31/3835; G01R 31/396; H01M 10/42

(52) U.S. Cl. CPC B60L 53/66; B60L 53/11; B60L 53/62; B60L 53/67; G01R 31/3835; G01R 31/396; H01M 10/4285; H01M 2220/20

(57) ABSTRACT

A method and system for diagnosing and evaluating a state of battery. The system for diagnosing and evaluating a state of an electric vehicle battery includes: a charging/discharging system that provides a direct high-voltage path for simultaneous charging and discharging between a diagnosis target vehicle (EV1) and a center vehicle (EV2), and a diagnostic device that obtains vehicle data corresponding to each of the charging and discharging from the EV1 through diagnostic communication and diagnoses and evaluates a state of a battery of the EV1 based on the vehicle data. In particular, energy discharged from a battery of the EV2 is charged to the battery of the EV1 through the charging/discharging system after energy discharged from the battery of the EV1 is charged to the battery of the EV2 through the charging/discharging system.

### CROSS-REFERENCE TO RELATED APPLICATION

This application claims the benefit of and priority to Korean Patent Application No. 10-2024-0131018, filed in the Korean Intellectual Property Office on Sep. 26, 2024, the entire contents of which are incorporated herein by reference.

### TECHNICAL FIELD

The present disclosure relates to a vehicle diagnostic apparatus, a system including the vehicle diagnostic apparatus and a method for diagnosing a vehicle, and more particularly, to a technology for diagnosing and evaluating the state of an EV (electrical vehicle) battery through an EV-to-EV power transfer system.

### BACKGROUND

As the number of EV users has increased recently, the state of health (SOH) and abnormal state evaluation of an electric vehicle battery has become increasing important in relation to high-voltage battery state certification, EV used car certification, and remanufacturing. The SOH indicates how much performance a battery currently has compared to the initial performance of the battery, and is used as an indicator of the remaining battery life and current performance status.

A state of charge (SOC) refers to the amount of electricity that may be used from a battery cell, and is expressed as the ratio of the maximum charge amount initially available when the battery is shipped from the factory and the current charge amount. In other words, the SOC indicates the remaining electric energy or charge level of the battery, expressed as a percentage (%) of its full capacity. The SOH reflects the battery's overall health and degradation over time.

For the SOH and abnormal state evaluation, a process of charging and discharging the battery from an appropriate low SOC to a high SOC is required.

When the SOC of a battery of a vehicle brought into a center for battery state evaluation is not lower than a specified reference value (e.g., a predetermined low SOC value), the battery needs to be discharged to the reference value (e.g., the predetermined low SOC value). In the related art, the SOC of the battery is lowered below a reference value by traditional methods such as road driving, heater discharge, or the like. However, the traditional methods has the drawback of a low discharge capacity, resulting in a lot of man-hours as well as a long discharge time. In particular, because the existing traditional discharge scheme converts electrical energy into kinetic and/or thermal energy, not only does energy waste during discharge, but a lot of electrical energy is also required again to recharge the battery after discharge.

In the case of a dedicated charger/discharger introduced to replace the traditional discharge scheme, the time required for discharging may be reduced due to high power consumption, but the increased form factor requires high installation costs and a lot of space, and a separate electricity charge is incurred for the dedicated charger/discharger driven for discharging.

The statements in this Background section merely provide background information related to the present disclosure and may not constitute prior art.

### SUMMARY

The present disclosure has been made to solve the above-mentioned problems while advantages are maintained intact. In particular, the present disclosure provides EV battery state diagnosis and evaluation technology that may minimize the time and energy waste required for discharging without using a dedicated charger/discharger.

One aspect of the present disclosure provides a vehicle control apparatus for diagnosing and evaluating the state of a battery, a system including the vehicle control apparatus and a method for diagnosing and evaluating the state of a battery.

Another aspect of the present disclosure provides an apparatus for diagnosing and evaluating the state of an EV battery through an EV-to-EV power transfer system, a system including the apparatus and a method for diagnosing and evaluating the state of an EV battery through an EV-to-EV power transfer system.

The technical problems to be solved by the present disclosure are not limited to the aforementioned problems, and any other technical problems not mentioned herein should be clearly understood from the following description by those having ordinary skill in the art to which the present disclosure pertains.

According to one aspect of the present disclosure, a system for diagnosing and evaluating a state of an electric vehicle battery includes a charging and discharging system (which may also be referred to herein as a “charging/discharging system”) that provides a direct high-voltage path for charging and discharging between a diagnosis target vehicle (EV1) and a center vehicle (EV2), and a diagnostic device that obtains, from the EV1 through diagnostic communication, vehicle data corresponding to each of the charging and discharging and diagnoses and evaluates a state of a battery of the EV1 based on the vehicle data. Energy discharged from a battery of the EV2 is charged to the battery of the EV1 through the charging/discharging system after energy discharged from the battery of the EV1 is charged to the battery of the EV2 through the charging/discharging system.

According to an embodiment, the diagnostic device or the charging/discharging system may determine a time point at which to start a discharging and charging sequence for the battery of the EV1 based on a current state of charge (SOC) of the battery of the EV1.

According to an embodiment, the charging/discharging system may receive information about the current SOC of the battery of the EV1 from the diagnostic device to determine the time point at which to start the discharging and charging sequence for the battery of the EV1, and the diagnostic device may obtain the information about the current SOC of the battery of the EV1 through the diagnostic communication from the EV1.

According to an embodiment, the vehicle data corresponding to each of the charging and discharging may include at least one of an SOC, a maximum voltage (Vmax), or a minimum voltage (Vmin) of the battery of the EV1.

According to an embodiment, the charging/discharging system may compare the vehicle data with reference values corresponding to a current state of the battery to determine a time point at which to terminate the charging and discharging, and the current state may include a charging state and a discharging state.

According to an embodiment, the charging/discharging system may determine charging termination based on the SOC being equal to or greater than a predetermined charging termination SOC upper limit or the Vmax being equal to or greater than a predetermined charging termination cell voltage upper limit and the Vmin being equal to or greater than a predetermined charging termination cell voltage lower limit when the current state is the charging state or based on that the current state is the charging state, and determine discharging termination based on the SOC being lower than or equal to a predetermined discharging termination SOC lower limit or the Vmin being lower than or equal to a predetermined discharging termination cell voltage lower limit when the current state is the discharging state or based on that the current state is the discharging state.

According to an embodiment, the current state may further include a pause state, the charging/discharging system may determine an initiation time point of a pause sequence based on an intensity of a current flowing in the battery of the EV1, and determine an end time point of the pause state by comparing an amount of voltage change of all cells of the battery of the EV1 after initiating the pause sequence with a voltage reference value corresponding to a previous state, and the previous state may include the charging state and the discharging state.

According to an embodiment, the charging/discharging system may drive a pause timer upon initiation of the pause sequence and terminate the pause state based on expiration of the pause timer.

According to an embodiment, the charging/discharging system may include a plurality of fast chargers. The charging/discharging system may transmit a simulation signal for generating the direct high-voltage path to each of the EV1 and the EV2 through power line communication based on the EV1 and the EV2 being connected to different fast chargers, respectively, among the plurality of fast chargers, close a high-voltage relay of each of the EV1 and the EV2 based on the simulation signal, and generate the direct high-voltage path between a fast charging port and a high-voltage battery.

According to an embodiment, the diagnostic device may calculate a current charging and discharging depth of discharge (DOD) (which may also be referred to herein as a “current charging/discharging DOD”) based on information about a battery capacity specification and a current SOC corresponding to at least one of the EV1 or the EV2 obtained through the diagnostic communication, and determine and display at least one user-selectable diagnostic option by checking whether the current charging/discharging DOD is within an available range.

According to another aspect of the present disclosure, a method of diagnosing and evaluating a state of an electric vehicle battery includes generating, by a charging/discharging system, a direct high-voltage path for simultaneous charging and discharging between a diagnosis target vehicle (EV1) and a center vehicle (EV2); obtaining, by a diagnostic device and from the EV1 through diagnostic communication, vehicle data corresponding to each of the charging and discharging; and diagnosing and evaluating, by the diagnostic device, a state of a battery of the EV1 based on the vehicle data. Energy discharged from a battery of the EV2 is charged to the battery of the EV1 through the charging/discharging system after energy discharged from the battery of the EV1 is charged to the battery of the EV2 through the charging/discharging system.

According to an embodiment, the method may further include determining, by the diagnostic device or the charging/discharging system, a time point at which to start a discharging and charging sequence for the battery of the EV1 based on a current state of charge (SOC) of the battery of the EV1.

According to an embodiment, the method may further include receiving, by the charging/discharging system, information about the current SOC of the battery of the EV1 from the diagnostic device to determine the time point at which to start the discharging and charging sequence for the battery of the EV1. In particular, the diagnostic device is configured to obtain the information about the current SOC of the battery of the EV1 through the diagnostic communication from the EV1.

According to an embodiment, the vehicle data corresponding to each of the charging and discharging may include at least one of an SOC, a maximum voltage (Vmax), or a minimum voltage (Vmin) of the battery of the EV1.

According to an embodiment, the method may further include comparing, by the charging/discharging system, the vehicle data with reference values corresponding to a current state of the battery to determine a time point at which to terminate the charging and discharging. The current state of the vehicle includes a charging state and a discharging state of the battery.

According to an embodiment, the method may further include: determining, by the charging/discharging system, charging termination based on the SOC being equal to or greater than a charging termination SOC upper limit or the Vmax being equal to or greater than a predetermined charging termination cell voltage upper limit and the Vmin being equal to or greater than a predetermined charging termination cell voltage lower limit when the current state is the charging state or based on that the current state is the charging state; and determining, by the charging/discharging system, discharging termination based on the SOC being lower than or equal to a predetermined discharging termination SOC lower limit or the Vmin being lower than or equal to a predetermined discharging termination cell voltage lower limit when the current state is the discharging state or based on that the current state is the discharging state.

According to an embodiment, the current state may further include a pause state. The method may further include: determining, by the charging/discharging system, an initiation time point of a pause sequence based on an intensity of a current flowing in the battery of the EV1; and determining, by the charging/discharging system, an end time point of the pause state by comparing an amount of voltage change of all cells of the battery of the EV1 after initiating the pause sequence with a voltage reference value corresponding to a previous state. The previous state may include the charging state and the discharging state.

According to an embodiment, the method may further include driving, by the charging/discharging system, a pause timer upon initiation of the pause sequence, and terminating, by the charging/discharging system, the pause state based on expiration of the pause timer.

According to an embodiment, the charging/discharging system may include a plurality of fast chargers. The method may further include transmitting, by the charging/discharging system, a simulation signal for generating the direct high-voltage path to each of the EV1 and the EV2 through power line communication based on the EV1 and the EV2 being connected to different fast chargers, respectively, among the plurality of fast chargers. High-voltage relays of the EV1 and the EV2 may be closed based on the simulation signal, and the direct high-voltage path is generated between a fast charging port and a high-voltage battery.

According to an embodiment, the method may further include calculating, by the diagnostic device, a current charging/discharging depth of discharge (DOD) based on information about a battery capacity specification and a current SOC corresponding to at least one of the EV1 or the EV2 obtained through the diagnostic communication, and determining and displaying, by the diagnostic device, at least one user-selectable diagnostic option by checking whether the current charging/discharging DOD is within an available range.

### BRIEF DESCRIPTION OF THE DRAWINGS

The above and other objects, features and advantages of the present disclosure should be more apparent from the following detailed description taken in conjunction with the accompanying drawings:

FIG. 1 is a diagram illustrating a system for diagnosing and evaluating a state of an electric vehicle battery according to an embodiment of the present disclosure;

FIG. 2 is a flowchart illustrating a method of diagnosing and evaluating an electric vehicle battery according to an embodiment of the present disclosure;

FIG. 3 is a diagram illustrating the detailed structure of a charging/discharging system according to an embodiment of the present disclosure;

FIG. 4 is a diagram illustrating the detailed structure of a system for diagnosing and evaluating an electric vehicle battery according to an embodiment of the present disclosure;

FIG. 5 is a flowchart illustrating a method of operating a charging/discharging system according to an embodiment of the present disclosure;

FIG. 6 is a flowchart illustrating a method of operating a diagnostic device according to an embodiment of the present disclosure;

FIG. 7 is a diagram illustrating information transmitted and received between components in a system for diagnosing and evaluating a state of an electric vehicle battery according to an embodiment of the present disclosure;

FIG. 8 is a flowchart illustrating a method of diagnosing and evaluating a state of an electric vehicle battery according to an embodiment of the present disclosure;

FIG. 9 is a flowchart illustrating a method of ending a pause state according to an embodiment of the present disclosure;

FIG. 10 is a flowchart illustrating a charging/discharging termination method according to an embodiment of the present disclosure; and

FIG. 11 is a block diagram illustrating a computing system according to an embodiment of the present disclosure.

The drawings described herein are for illustration purposes only and are not intended to limit the scope of the present disclosure in any way.

### DETAILED DESCRIPTION

Hereinafter, some embodiments of the present disclosure are described in detail with reference to the drawings. In adding the reference numerals to the components of each drawing, it should be noted that the identical or equivalent component is specified by the identical numeral even when they are displayed on other drawings. Further, in describing embodiments of the present disclosure, a detailed description of the related known configuration or function has been omitted when it is determined that it interferes with the understanding of embodiments of the present disclosure.

Terms, such as first, second, A, B, (a), (b) or the like may be used herein when describing components of the present disclosure. The terms are provided only to distinguish the elements from other elements, and the essences, sequences, orders, and numbers of the elements are not limited by the terms. In addition, unless defined otherwise, all terms used herein, including technical or scientific terms, have the same meanings as those generally understood by those having ordinary skill in the art to which the present disclosure pertains. The terms defined in the generally used dictionaries should be construed as having the meanings that coincide with the meanings of the contexts of the related technologies, and should not be construed as ideal or excessively formal meanings unless clearly defined in the specification of the present disclosure.

When a component, controller, device, element, apparatus, system, or the like of the present disclosure is described as having a purpose or performing an operation, function, or the like, the component, controller, device, element, apparatus, system, or the like should be considered herein as being “configured to” meet that purpose or to perform that operation or function. Each component, controller, device, element, apparatus, system and the like may separately embody or be included with a processor and a memory, such as a non-transitory computer readable media, as part of the apparatus.

In the present disclosure, each of phrases such as “A or B”, “at least one of A and B”, “at least one of A or B”, “A, B or C”, “at least one of A, B and C”, “at least one of A, B or C” and “at least one of A, B, or C, or a combination thereof” may include any one or all possible combinations of the items listed together in the corresponding one of the phrases.

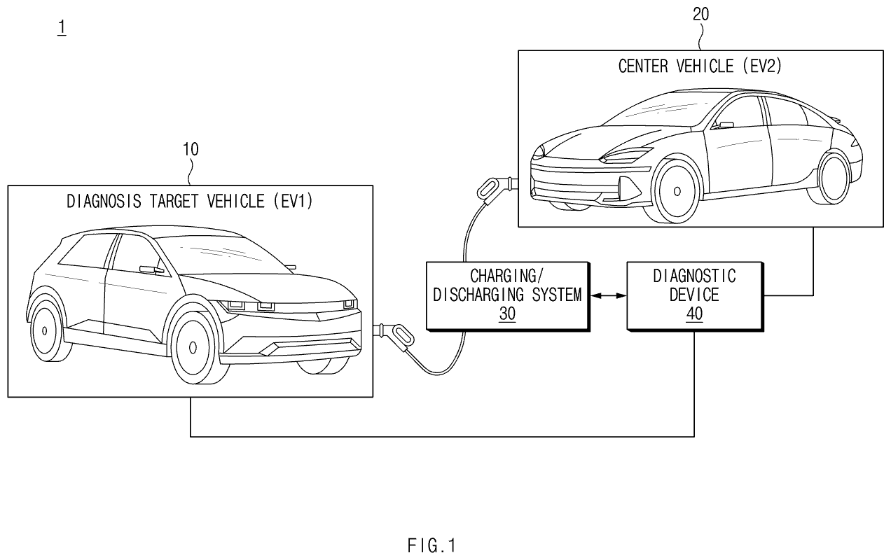

Hereinafter, embodiments of the present disclosure are described in detail with reference to FIGS. 1 to 11.

FIG. 1 is a diagram illustrating a system for diagnosing and evaluating a state of an electric vehicle battery according to an embodiment of the present disclosure.

Referring to FIG. 1, a system 1 for diagnosing and evaluating a state of a battery may schematically include a diagnosis target vehicle (EV1) 10, a center vehicle (EV2) 20, a charging/discharging system 30, and a diagnostic device 40.

When the EV1 10, which is a battery diagnosis and evaluation target vehicle, is brought into a center, the EV1 10 and the EV2 20 may be connected via a charging cable (or a fast charger) provided in the charging/discharging system 30. A fast charger is a high-power charging device or system that delivers energy at a significantly higher rate than conventional chargers, reducing the charging time of a battery by increasing voltage, current, or both, while ensuring safety and efficiency through advanced charging protocols.

The EV1 10 and the EV2 20 may transmit and receive signals for charging/discharging and charging/discharging energy through the connected charging cable to and from the charging/discharging system 30.

The diagnostic device 40 may be connected to an on-board diagnostics (OBD) terminal provided in each of the EV1 10 and the EV2 20 to perform diagnostic communication, and a separate communication channel may be set up to transmit and receive signals with the charging/discharging system 30. For example, the charging/discharging system 30 and the diagnostic device 40 may be connected via a wired cable such as a USB (universal serial bus) cable, an HDMI (high-definition video device) cable, an Ethernet cable, or the like, but this is only one embodiment, and may be connected through wireless communication such as Bluetooth communication, Wi-Fi communication, 4G Long-Term Evolution (LTE) communication, 5G new radio (NR) communication, or the like.

For diagnosis and evaluation, discharge of the battery of the EV1 10 to a specified diagnostic initiation reference SOC level is required.

As an example, energy discharged from the battery of EV1 10 may be directly transferred to the EV2 20 through the charging/discharging system 30 and used to charge the battery of the EV2 20. In other words, the charging of a center vehicle battery may be performed simultaneously with the discharge of a diagnosis target battery.

The charging/discharging system 30 may generate a specified simulation signal such that the EV1 10 recognizes the charging/discharging system 30 as a super-fast charger. The EV1 10 may determine that the EV1 10 is connected to a high-fast charger based on the received simulation signal and may generate a high-voltage path from the fast charger port to the high-voltage battery.

In addition, the charging/discharging system 30 may generate a specified simulation signal such that the EV2 20 recognizes the charging/discharging system 30 as a high-fast charger. The EV1 10 may determine that the EV1 10 is connected to a high-speed charger based on the received simulation signal and may generate a high-voltage path from the fast charger port to the high-voltage battery.

As an example, when it is confirmed that the diagnostic device 40 is connected to the EV1 10 and the EV2 20 through diagnostic communication and the EV1 10 and the EV2 20 are connected to the charging/discharging system 30, the diagnostic device 40 may control the charging/discharging system 30 to generate the simulation signal for generating the high-voltage path and transmit the simulation signal to the EV1 10 and the EV2 20. However, this is only one example, and the charging/discharging system 30 may also automatically generate the simulation signal based on the connection of power line communication with the EV1 10 and the EV2 20.

As a result, the charging/discharging system 30 may control to form a high-voltage path between two vehicles that are electrically isolated (separated) but magnetically coupled through the above-described simulation signal.

The charging/discharging system 30 may be equipped with a high-frequency DC/DC power converter to convert energy discharged from one vehicle and transmit the energy to another vehicle.

Most of the energy discharged by one vehicle may be used to charge other vehicles, and only a portion of the discharged energy may result in loss due to power conversion within the charging/discharging system 30.

The EV1 10 may stop discharging and enter a pause state when the SOC reaches a specified reference value. For example, the EV1 10 may transmit battery status information to the diagnostic device 40, and the diagnostic device 40 may transmit a specified control signal requesting discharge stop to the EV1 10 when the SOC of the EV1 10 reaches the specified reference value based on the battery status information. As another example, the diagnostic device 40 may transmit information about an SOC reference value for stopping discharge to the EV1 10, and the EV1 10 may stop discharging and enter a pause state when the current SOC reaches the SOC reference value. The operation in the pause state should become clearer with the description of the drawings that follow.

After the pause state ends, the EV1 10 may switch to a charging state and receive the energy discharged by the EV2 20 through the charging/discharging system 30 to charge its own battery.

The diagnostic device 40 may collect discharging and charging data from the EV1 10 and perform a diagnosis and evaluation on the battery of the EV1 10 based on the collected discharging and charging data. For example, discharging and charging data may be collected after discharging and charging are terminated, but this is only one embodiment and may be collected at a specified interval.

As described above, the system 1 for diagnosing and evaluating a state of an electric vehicle battery according to the present disclosure may significantly reduce the time required for charging/discharging a diagnosis target vehicle by simultaneously performing EV to EV fast charging/discharging through the charging/discharging system 30, and may also provide a function of diagnosing and evaluating the state of a high-voltage battery that minimizes energy waste by recycling discharged energy back into charging energy.

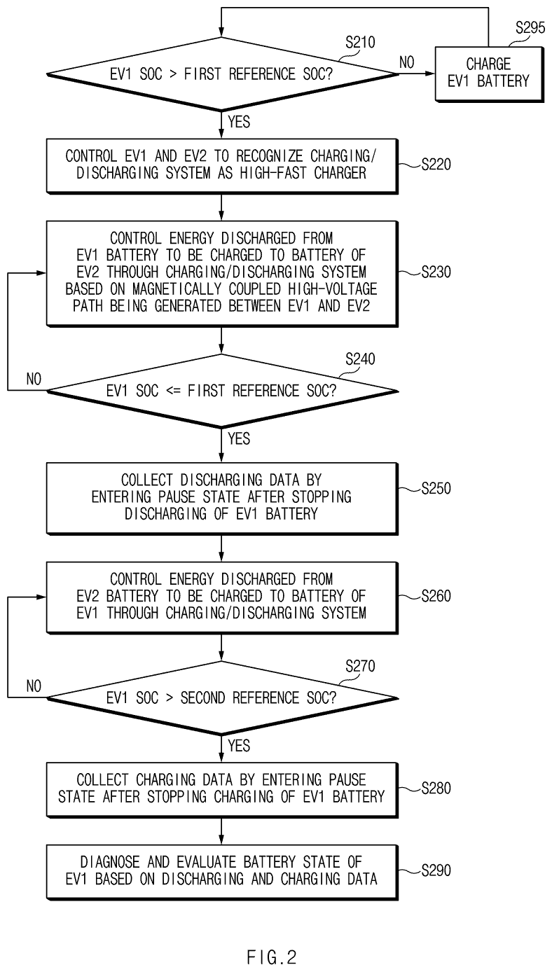

FIG. 2 is a flowchart illustrating a method of diagnosing and evaluating an electric vehicle battery according to an embodiment of the present disclosure.

Referring to FIG. 2, in S210, the system 1 for diagnosing and evaluating an electric vehicle battery may compare the SOC of the EV1 10 with a first reference SOC to determine whether the battery of the EV1 10 is discharged.

As a comparison result, when the SOC of EV1 exceeds the first reference SOC, in S220, the system 1 for diagnosing and evaluating an electric vehicle battery may control the EV1 10 and the EV2 20 to recognize the charging/discharging system 30 as a high-fast charger. For example, the charging/discharging system 30 may control the EV1 10 and the EV2 20 to recognize the charging/discharging system 30 as a high-fast charger by transmitting a specified simulation signal to the EV1 10 and the EV2 20, and each of the EV1 10 and the EV2 20 may generate a high-voltage path between their own fast charging port and the high-voltage battery according to the detected simulation signal. In this case, a magnetically coupled high-voltage path may be formed between the EV1 10 and the EV2 20.

In S230, the system 1 for diagnosing and evaluating an electric vehicle battery may control the energy discharged from the battery of the EV1 10 to be charged into the battery of the EV2 20 through the charging/discharging system 30 based on the magnetically coupled high-voltage path being generated between the EV1 10 and the EV2 20.

In S240 and S250, the system 1 for diagnosing and evaluating an electric vehicle battery may collect discharging data by stopping the discharge of the battery of the EV 10 and entering a pause state based on the SOC of the EV1 10 reaching the first reference SOC. For example, the diagnostic device 40 may obtain the discharging data from the EV1 10 through diagnostic communication.

In S260, the system 1 for diagnosing and evaluating an electric vehicle battery may control the discharged energy from the battery of the EV2 20 to be charged into the battery of the EV1 10 through the charging/discharging system 30.

In S270, the system 1 having the diagnostic device 40 may compare the SOC of EV1 10 with a second reference SOC which may be defined and set to a value greater than the first reference SOC. For example, the diagnostic device 40 may obtain charging data from the EV1 10 through diagnostic communication and the system 1 may determine that the SOC of the EV1 10 exceeds the second reference SOC.

In S280, upon determining that the SOC of the EV1 10 exceeds the second reference SOC in S270, the system 1 for diagnosing and evaluating an electric vehicle battery may collect charging data by stopping EV1 10 battery charging and entering a pause state based on the SOC of EV1 10 exceeding the second reference SOC.

In S290, the system 1 for diagnosing and evaluating an electric vehicle battery may diagnose and evaluate the battery state of the EV1 10 based on discharging and charging data. For example, the diagnosis and evaluation of the battery state of the EV1 10 may be performed by the diagnostic device 40, and the diagnosis and evaluation result may be output through a display (not shown) provided in the diagnostic device 40. In addition, the diagnosis and evaluation results may be transmitted to a cloud server (not shown) connected to a communication network (not shown).

When the SOC of the EV1 10 is less than the first reference SOC in S210 and S295, the system 1 for diagnosing and evaluating an electric vehicle battery may perform charging of the battery of the EV1 10 until the SOC of the EV1 10 exceeds the first reference SOC. For example, the charging/discharging system 30 may convert energy discharged from the battery of the EV2 20 to charge the battery of the EV1 10 according to the control signal of the diagnostic device 40.

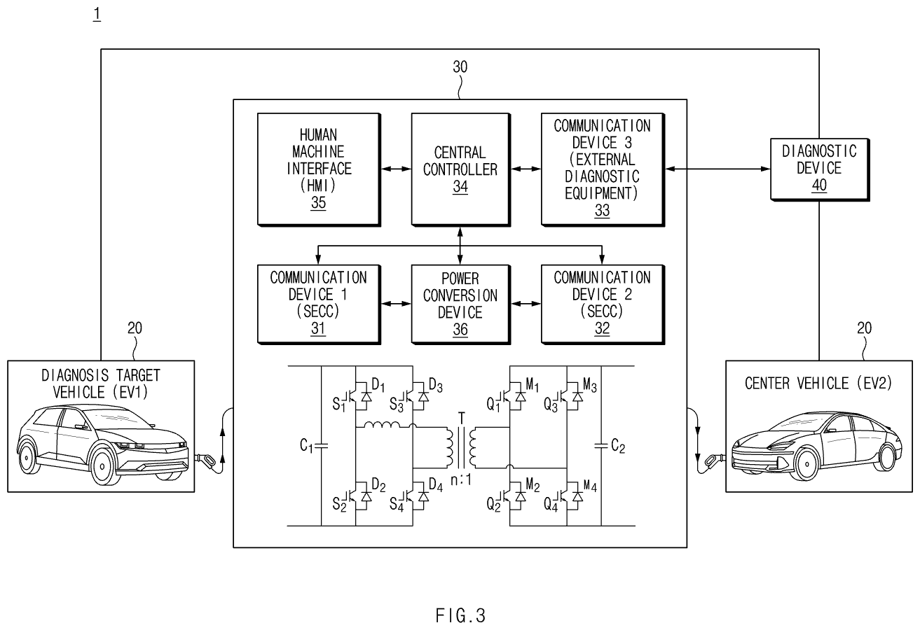

FIG. 3 is a diagram illustrating the detailed structure of a charging/discharging system according to an embodiment of the present disclosure.

Referring to FIG. 3, the charging/discharging system 30 may include first to third communication devices 31 to 33, a central controller 34, an human machine interface (HMI) 35, and a power conversion device 36.

The first communication device 31 may communicate with the EV1 10, the second communication device 32 may communicate with the EV2 20, and the third communication device 33 may communicate with the diagnostic device 40.

Each of the first and second communication devices 31 and 32 of the charging/discharging system 30 may be provided with a supply equipment communication controller (SECC), which is a supply equipment communication controller, and each of the EV1 10 and the EV2 20 may be provided with an electric vehicle communication controller (EVCC), which is an electric vehicle communication controller, so that it is possible to perform mutual communication. For example, the SECC and the EVCC may set up a charging session and exchange information with each other according to protocols specified in the German technical standard DIN 70121 or the international standards organization ISO 15118-2 & 20. As an example, the charging/discharging system 30 may control (or induce) the EV1 10 and the EV2 20 to close the high-voltage relays by using a specified control signal according to the protocol specified in DIN 70121 or ISO 15118-2 & 20. An inverter and converter of an EV and a high-voltage battery are connected via relays. In other words, when driving an electric motor or charging the high-voltage battery, the EV may control the high-voltage relay to connect the high-voltage battery to the electric motor (load) or to an on-board charger (OBC).

The third communication device 33 may be provided with a vehicle diagnostic communication connector such as an OBD-II (On-Board Diagnostic II) terminal and be connected to the diagnostic device 40, but this is only one embodiment, and may communicate with the diagnostic device 40 through Bluetooth communication, Wi-Fi communication, or mobile communication. For example, the unified diagnostic service (UDS) defined in ISO 14291-1 may be applied to diagnostic communication, but this is only one embodiment, and other diagnostic communication schemes may be applied depending on the implementation by those having ordinary skill in the art.

The diagnostic device 40 may be connected through a diagnostic communication connector such as an OBD-II terminal provided in each of the EV1 10 and the EV2 20 to exchange signals and information with the corresponding electric control unit (ECU) of the corresponding EV. In this case, the ECU may include an ECU such as a battery management system (BMS) that manages the state of the high-voltage battery.

The central controller 34 may control the overall input/output and sub-modules of the charging/discharging system 30. In this case, the sub-module may include the first to third communication devices 31 to 33, the HMI 35, and the power conversion device 36.

The HMI 35 may provide a user interface for input and output. For example, the HMI 35 may include various input/output devices such as a keypad, a jog wheel, a display, a button, a switch, and the like. The central controller 34 may output at least one piece of information about a charging/discharging state and target setting information for charging/discharging through the display. In addition, the central controller 34 may collect battery state information of the EV1 10 and the EV2 20 from the diagnostic device 40 and display it on the display.

The power conversion device 36 may perform power conversion for charging/discharging between the EV1 10 and the EV2 20 according to the control signal of the central controller 34. As an example, the central controller 34 may set the power conversion ratio for charging and/or discharging to the power conversion device 36 based on the discharge and/or charge target values input through the diagnostic device 40. For example, the target value may include an SOC, a pack voltage, a cell voltage, and the like, but embodiments are not limited thereto. In this case, the target value may be determined by considering the current available charging/discharging capacity of each vehicle.

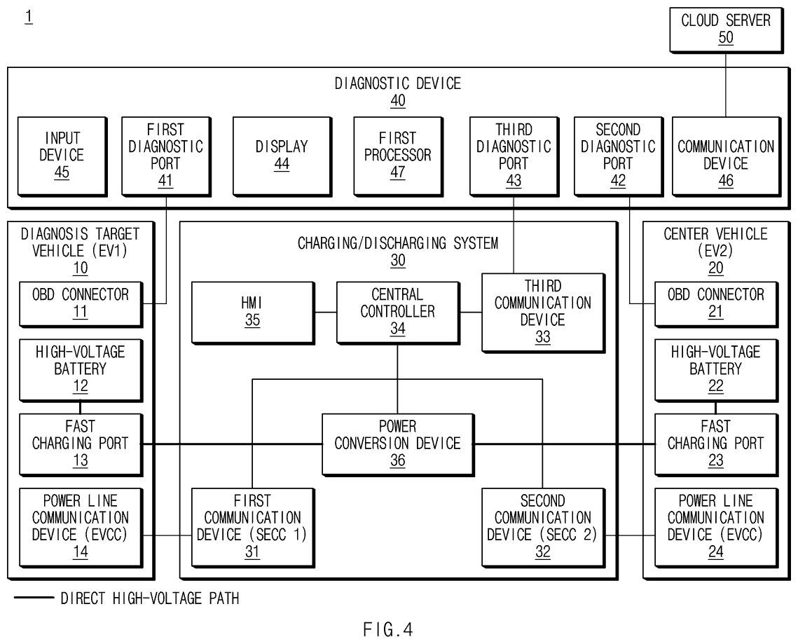

FIG. 4 is a diagram illustrating the detailed structure of a system for diagnosing and evaluating an electric vehicle battery according to an embodiment of the present disclosure.

Referring to FIG. 4, the system 1 for diagnosing and evaluating an electric vehicle battery may substantially include the EV1 10, the EV2 20, the charging/discharging system 30, the diagnostic device 40, and a cloud server 50. In this case, the diagnostic device 40 and the cloud server 50 may be connected through a wired and/or wireless communication network.

Each of the EV1 10 and the EV2 20 may include an OBD connector 11 or 21, a high-voltage battery 12 or 22, a fast charging port 13 or 23, and a power line communication device 14 or 24.

The diagnostic device 40 may include at least one of first to third diagnostic ports 41 to 43, a display 44, an input device 45, a communication device 46, and a processor 47.

The first diagnostic port 41 may be connected to the OBD connector 11 of the EV1 10, the second diagnostic port 42 may be connected to the OBD connector 21 of the EV2 20, and the third diagnostic port 43 may be connected to the third communication device 33 of the charging/discharging system 30.

The power line communication device 14 of the EV1 10 may be connected to the first communication device 31 of the charging/discharging system 30, and the power line communication device 24 of the EV2 20 may be connected to the second communication device 32 of the charging/discharging system 30.

The charging/discharging system 30 may control each EV to close a high-voltage relay and generate a high-voltage path between the high-voltage battery 12 or 22 and the fast charging port 13 or 23 by transmitting a specified simulation signal to the EV1 10 and the EV2 20 through the first communication device 31 and the second communication device 32. Thus, a path for direct high-voltage charging/discharging may be formed between the high-voltage battery 12 of the EV1 10 and the high-voltage battery 22 of the EV2 20.

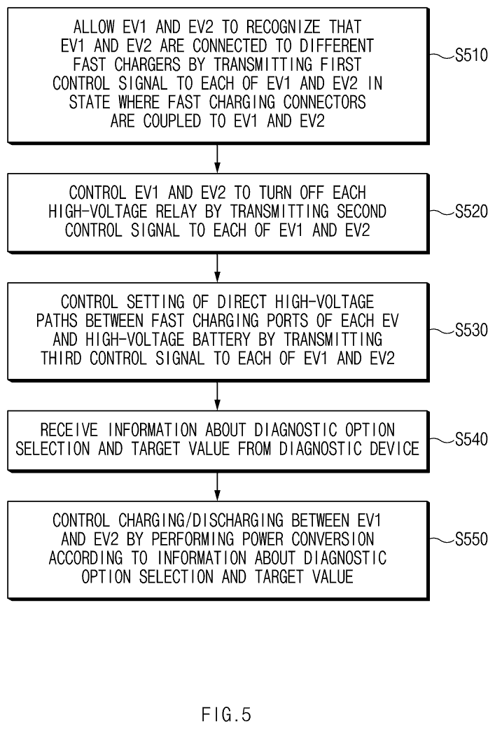

FIG. 5 is a flowchart illustrating a method of operating a charging/discharging system according to an embodiment of the present disclosure.

Referring to FIGS. 4 and 5, when the charging/discharging system 30 confirms that the fast charging connectors are normally connected to the EV1 10 and the EV2 20, in S510, the charging/discharging system 30 may transmit a first control signal to each of the EV1 10 and the EV2 20 to allow the EV1 10 and the EV2 20 to recognize that they are connected to different fast chargers.

In S520, the charging/discharging system 30 may control the EV1 10 and the EV2 20 to turn off each high-voltage relay by transmitting the first control signal to each of the EV1 10 and the EV2 20.

In S530, the charging/discharging system 30 may control the generation of direct high-voltage paths between the fast charging ports 13 and 23 of each EV (i.e., EV1 and EV2) and the high-voltage batteries 12 and 22 by transmitting the first control signal to each of the EV1 10 and the EV2 20.

In S540, the charging/discharging system 30 may receive information about diagnostic option selection and target values from the diagnostic device 40. In this case, the target value may include at least one of an SOC, a pack voltage, or a cell voltage for a battery.

In S550, the charging/discharging system 30 may control charging/discharging between the EV1 10 and the EV2 20 by performing power conversion based on the information about diagnostic option selection and target values.

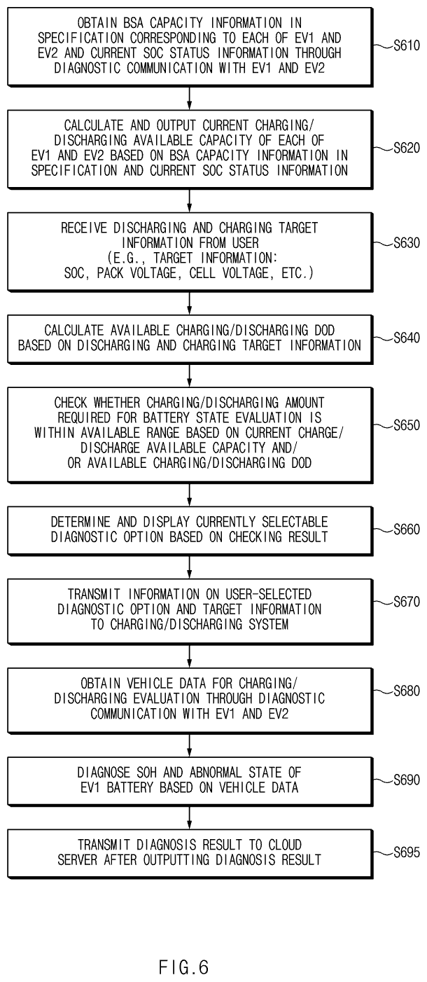

FIG. 6 is a flowchart illustrating a method of operating a diagnostic device according to an embodiment of the present disclosure.

Referring to FIGS. 4 and 6, in S610, the diagnostic device 40 may obtain capacity information of the battery system assembly (BSA) in the specifications corresponding to each of the EV1 10 and the EV2 20 and current SOC status information through diagnostic communication with the EV1 10 and the EV2 20. In this case, the BSA refers to a finished product that combines a battery pack with electrical components and a battery management system (BMS) to ensure that the battery operates safely and efficiently in an electric vehicle, and a high-capacity/high-efficiency battery system is a main component that determines the quality and performance of an electric vehicle.

In S620, the diagnostic device 40 may calculate and output the current charge/discharge available capacity of each of the EV1 10 and the EV2 20 based on the BSA capacity information in the specifications and the current SOC status information. For example, the current charge/discharge available capacity may be calculated as the current charge/discharge DOD.

In S630, the diagnostic device 40 may receive discharging and charging target information from the user through the provided input device. In this case, the target information may include an SOC, a pack voltage, a cell voltage, and the like, but embodiments are not limited thereto.

In S640, the diagnostic device 40 may calculate the available charge/discharge depth of discharge (DOD) based on discharging and charging target information. In this case, the DOD is the opposite term of SOC and is an indicator of the discharge state of a battery. In other words, in the case of electric vehicles, the DOD indicates what percentage of the battery has been discharged from a fully charged state (i.e. SOC: 100%).

In S650, the diagnostic device 40 may check whether the charge/discharge amount required for battery state evaluation is within an available range based on the current charge/discharge available capacity and/or available charge/discharge DOD.

In S660, the diagnostic device 40 may determine the currently selectable diagnostic options based on the checking result in S650 and display them on a display screen. For example, when the discharge DOD is less than the available discharge DOD, the diagnostic device 40 may determine that the discharge diagnostic mode is executable. When the charge DOD is less than the available charge DOD, the diagnostic device 40 may determine that one of the SOC restoration mode upon receipt, the SOC setting mode upon shipment, or the charging diagnosis execution mode is executable.

In S670, the diagnostic device 40 may transmit information on user-selected diagnostic options and target information to the charging/discharging system 30. In this case, the target information may include a target SOC.

In S680, the diagnostic device 40 may obtain vehicle data for charge/discharge evaluation through diagnostic communication with the EV1 10 and the EV2 20.

In S690, the diagnostic device 40 may diagnose the SOH and abnormal state of the battery of the EV1 10 based on vehicle data.

In S695, the diagnostic device 40 may output a result of diagnosing the battery of the EV1 10 to the cloud server 50 after outputting the diagnosis result onto the display screen.

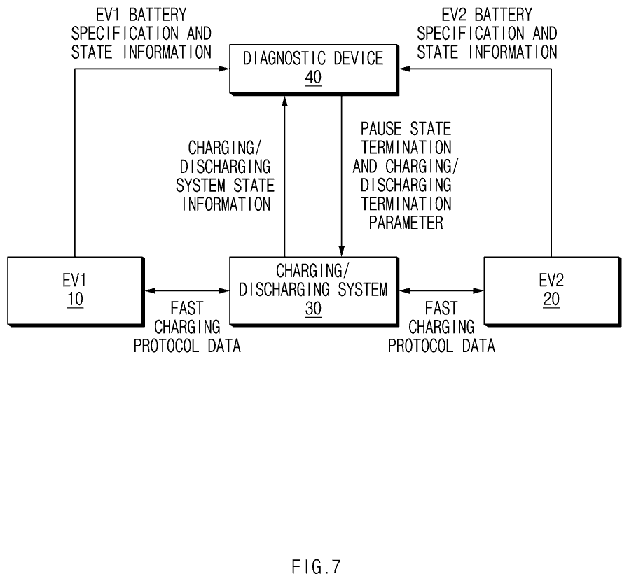

FIG. 7 is a diagram illustrating information transmitted and received between components in a system for diagnosing and evaluating a state of an electric vehicle battery according to an embodiment of the present disclosure.

Referring to FIG. 7, the diagnostic device 40 may obtain a battery specification and status information including at least one of power per unit time (Capacity [kWh]), a cell voltage (V.cell [mV]), a pack voltage (V.pack [V]), a cell temperature (T.cell [C]), a state of charge (SOC [%]), a pack current (Ipack [A]), and an amount of charges per unit time (Iaccumul.[Ah]) of the BSA in the specification from the EV1 10 and the EV2 20 through diagnostic communication.

The diagnostic device 40 may receive current status information from the charging/discharging system 30. In this case, the current status information may include at least one piece of first status information (Ready) indicating whether preparation for charging/discharging is complete, second status information (Fault) indicating whether there is an error state, third status information (Pre-chg) related to pre-charge, and fourth status information indicating whether connected EVs are in a charging mode (Chg) or discharging mode (Dchg).

The diagnostic device 40 may transmit reference parameters for determining the end of the pause state and the end of charging/discharging to the charging/discharging system 30. For example, a reference parameter value for determining the end of the pause state may include a full cell voltage drop reference value (ΔV.relax.down) and a pause timer (T.relax) value, and a reference parameter value for determining the end of charge/discharge may include a charge end SOC upper limit value (ChgStop.SOC.max), a discharge end SOC lower limit value (DchgStop.SOC.min), a charge end cell voltage upper limit value (ChgStop.Vcell.max), a charge end cell voltage lower limit value (ChgStop.Vcell.min), and a discharge end cell voltage lower limit value (DchgStop.Vcell.min).

The charging/discharging system 30 and each EV may transmit and receive data according to a fast charging protocol.

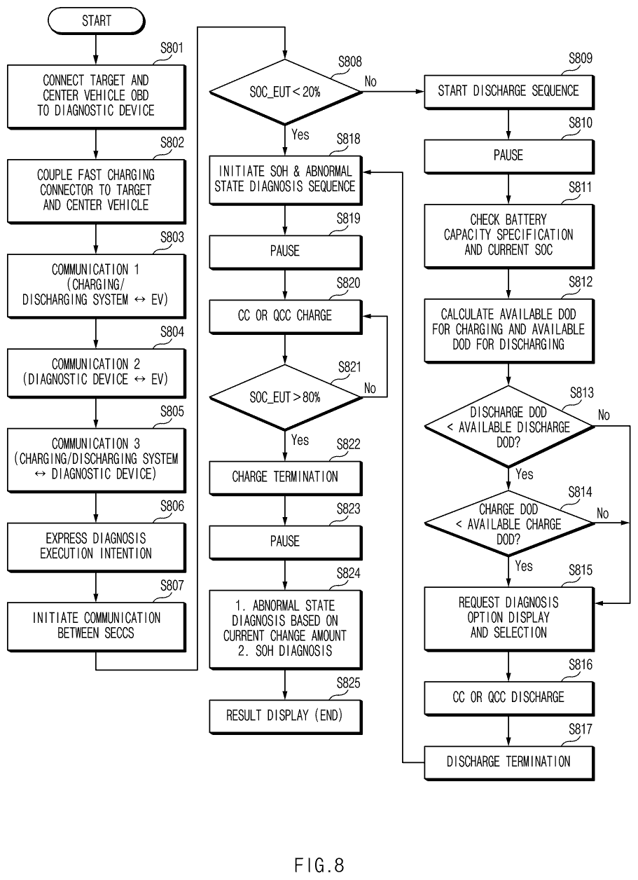

FIG. 8 is a flowchart illustrating a method of diagnosing and evaluating a state of an electric vehicle battery according to an embodiment of the present disclosure.

Referring to FIGS. 4 and 8, after connecting the diagnostic device 40 to the OBD connectors 11 and 21 of the EV1 10, which is a diagnosis target vehicle, and the EV2 20, which is a center vehicle, the fast charging connector provided in the charging/discharging system 30 may be coupled to the fast charging ports 13 and 23 of the EV1 10 and the EV2 20 in S801 and S802.

In S803, the charging/discharging system 30 may set up a first communication channel for controlling charging/discharging with the EV1 10 and the EV2 20.

In S804, the diagnostic device 40 may set up a second communication channel for diagnostic communication with the EV1 10 and the EV2 20. In addition, in S805, the diagnostic device 40 may set up a third communication channel for transmitting and receiving information with the charging/discharging system 30.

When the user's intention to perform a diagnosis is expressed through the diagnostic device 40, in S806 and S807, the charging/discharging system 30 may initiate communication with the EVCCs 14 and 24 of the EV1 10 and the EV2 20 by driving the SECCs 31 and 32.

In S808 and S809, the diagnostic device 40 may control the charging/discharging system 30 to start a discharge sequence for the battery of the EV1 10 based on the SOC of the EV1 10, which is a diagnosis target vehicle, being less than the first reference value. For example, the first reference value may be set to 20%, but this is only one embodiment and may be set to a different value depending on the design of a person having ordinary skill in the art.

In S810 to S812, after the discharge sequence starts, the diagnostic device 40 may enter the pause state and check the battery capacity specifications and current SOC of the EV1 10 and the EV2 20 and then calculate the available DOD for charging and available DOD for discharging.

In S813 to S815, the diagnostic device 40 may display at least one diagnostic option based on the discharge DOD being less than the available discharge DOD and the charge DOD being less than the available charge DOD, and may request the user to select one of the displayed diagnostic options.

In S816, the diagnostic device 40 may perform discharging of the battery of the EV1 10 by controlling the charging/discharging system 30 according to the user-selected diagnostic option. In this case, discharging may be performed using one of a normal charging connector CC or a fast charging connector QCC.

When discharge is terminated, in S817 to S819, the diagnostic device 40 may enter a pause state after initiating an SOH evaluation and abnormal state diagnosis sequence for the battery of the EV1 10.

In S820, the diagnostic device 40 may initiate charging of the battery of the EV1 10 after the pause state is terminated. In this case, charging may be performed using one of the normal charging connector CC and the fast charging connector QCC.

In S821 to S823, the diagnostic device 40 may enter a pause state after terminating charging based on the SOC of the battery of the EV1 10 being equal to or greater than a specified second reference value.

In S824, the diagnostic device 40 may diagnose an abnormal state of the battery of the EV1 10 and perform SOH diagnosis based on the current change amount of the battery of the EV1 10.

In S825, the diagnostic device 40 may output the diagnosis and evaluation results for the battery state of the EV1 10 through the equipped display.

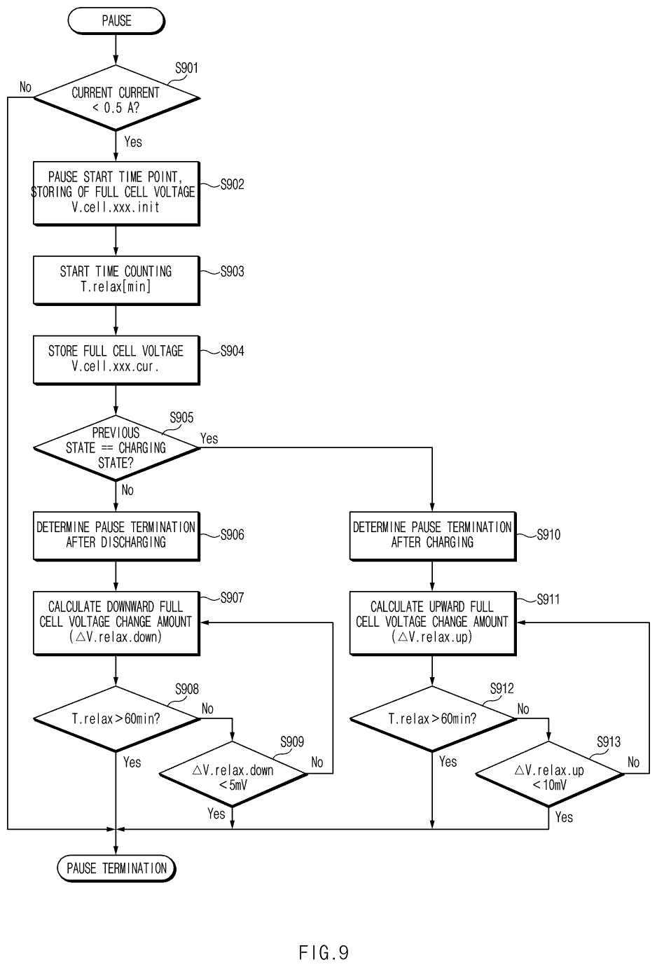

FIG. 9 is a flowchart illustrating a method of ending a pause state according to an embodiment of the present disclosure.

As an example, the determination of whether the pause state is ended may be performed by the diagnostic device 40, but this is only one embodiment, and according to another embodiment, the determination of whether the pause state is ended may be also performed by the charging/discharging system 30. The following description focuses on an example of the diagnostic device 40 determining whether the pause state is interrupted.

Referring to FIG. 9, in S901, the diagnostic device 40 may compare the present current value flowing in the battery of a diagnosis target vehicle with a specified reference current value to determine the time point when entering the pause state, i.e., the time point when the pause state starts. For example, the reference current value may be set to 0.5 A, and it is possible to enter the pause when the present current value is less than 0.5 A.

In S902 and S903, the diagnostic device 40 may obtain the initial battery full cell voltage value (V.cell.xxx.init) from the diagnosis target vehicle after entering the pause state and store it in an internal memory, and then start counting of a pause timer (T.relax). For example, the pause timer may be set to 60 minutes, but this is only one embodiment and may be set to longer or shorter time as designed by those having ordinary skill in the art.

The diagnostic device 40 may obtain the current full cell voltage value (V.cell.xxx.cur) from the diagnosis target vehicle at regular intervals and store it in the internal memory.

In S905, the diagnostic device 40 may check whether the previous state is a charging state or a discharging state.

In S906, the diagnostic device 40 may enter a post-charge pause termination decision mode based on the previous state being a charging state. To the contrary, when the previous state is a discharge state, the diagnostic device 40 may enter a post-discharge pause termination decision mode.

When entering the post-discharge pause termination decision mode, in S907, the diagnostic device 40 may calculate the downward full cell voltage change amount (ΔV.relax.down). In this case, the downward full cell voltage change amount may be calculated by subtracting V.cell.xxx.cur from V.cell.xxx.init.

When the pause timer is not expired, in S908 and S909, the diagnostic device 40 may compare ΔV.relax.down with the first voltage reference value to determine whether to end the pause. For example, the first voltage reference value may be set to 5 mV. In this case, the diagnostic device 40 may terminate the pause state when ΔV.relax.down is less than 5 mV.

When entering the post-charge pause termination decision mode, in S911, the diagnostic device 40 may calculate the upward full cell voltage change amount (ΔV.relax.up). In this case, the upward full cell voltage change amount may be calculated by subtracting V.cell.xxx.init from V.cell.xxx.cur.

When the pause timer has not expired, in S912 and S913, the diagnostic device 40 may compare ΔV.relax.up with the second voltage reference value to determine whether to end the pause. For example, the second voltage reference value may be set to 10 mV. In this case, the diagnostic device 40 may terminate the pause state when ΔV.relax.up is less than 10 mV.

The diagnostic device 40 may immediately end the pause state when the pause timer expires or the present current is greater than the reference current value.

As an example, the first and second voltage reference values may be determined as values that may be determined to be sufficiently small in the voltage change amount during discharging and charging, taking into account the error of the voltage sensor.

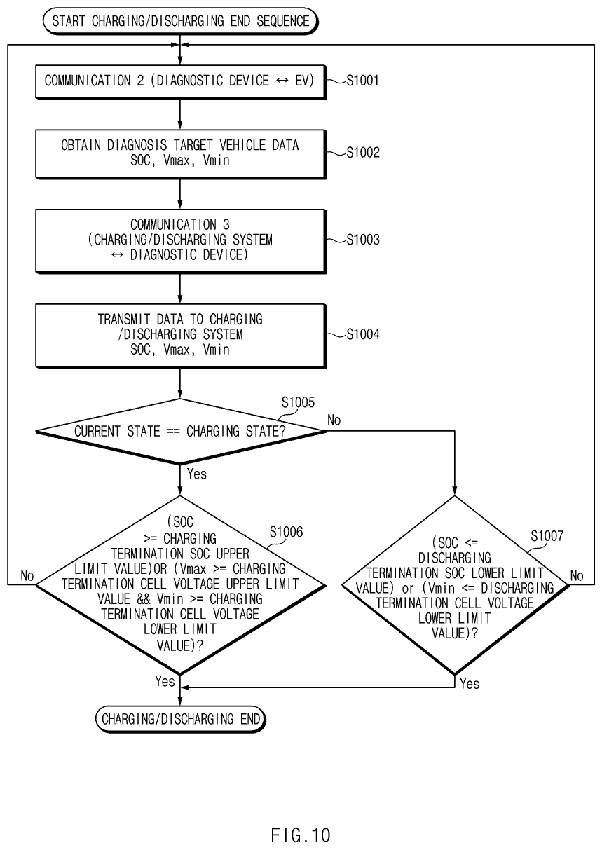

FIG. 10 is a flowchart illustrating a charging/discharging termination method according to an embodiment of the present disclosure.

As an example, the determination of whether charging/discharging is completed may be performed by the diagnostic device 40, but this is only one embodiment, and according to another embodiment, the determination of whether charging/discharging is completed may be performed by the charging/discharging system 30 in conjunction with the diagnostic device 40. The following description focuses on an example in which the charging/discharging system 30 determines whether to stop charging/discharging in conjunction with the diagnostic device 40.

In S1001 and S1002, the diagnostic device 40 may obtain diagnosis target vehicle data through diagnostic communication with the diagnosis target vehicle. In this case, the diagnosis target vehicle data may include data on the SOC, maximum voltage (Vmax), and minimum voltage (Vmin) of the battery of the diagnosis target vehicle, but embodiments are not limited thereto. The minimum voltage Vmin may refer to minimum value among a measured voltage for each of the battery cells. The maximum voltage Vmax may refer to maximum value among a measured voltage for each of the battery cells.

In S1003 and S1004, the diagnostic device 40 may transmit the diagnosis target vehicle data obtained through a communication channel connected to the charging/discharging system 30 to the charging/discharging system 30.

In S1005, the charging/discharging system 30 may check whether the current state is a charging state or a discharging state.

As the checking result, when the current state is a charging state, the charging/discharging system 30 may compare each of the SOC, Vmax, and Vmin with predefined reference values to determine whether to end charging. For example, the charging/discharging system 30 may determine charging termination when the SOC is equal to or greater than a charging termination SOC upper limit value or when the Vmax is equal to or greater than a charging termination cell voltage upper limit value and the Vmin is equal to or greater than a charging termination cell voltage lower limit value. The reference value related to the determination of the charging state termination may be applied as logic AND of the upper limit value and the lower limit value in order to be used as the SOC upper limit value and diagnosis data for determining whether the SOC is met for capacity evaluation.

As a checking result in S1005, when the current state is a discharge state, in S1007, the charging/discharging system 30 may compare each of the SOC and Vmin with predefined reference values to determine whether to end discharging. For example, the charging/discharging system 30 may determine discharge termination when the SOC is lower than or equal to the discharge termination SOC upper limit value or the Vmin is lower than or equal to the discharge termination cell voltage lower limit value. As the reference values related to the determination of the discharge state termination, the SOC lower limit value or cell voltage lower limit value may be applied for capacity evaluation or abnormal diagnosis evaluation.

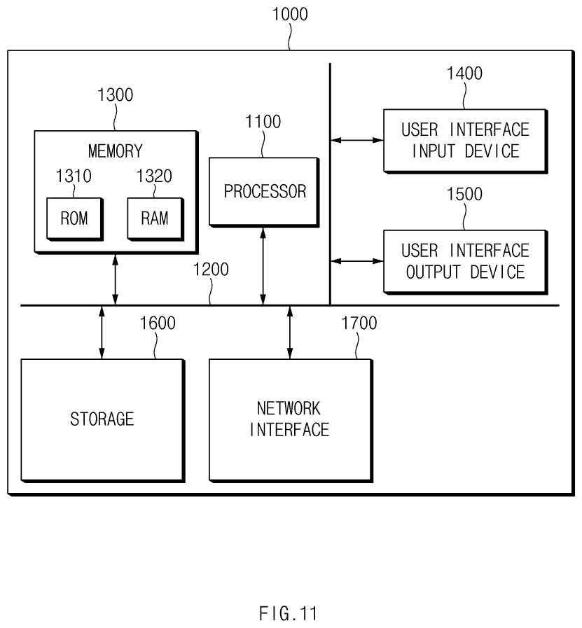

FIG. 11 is a block diagram illustrating a computing system according to an embodiment of the present disclosure.

Referring to FIG. 11, a computing system 1000 may include at least one processor 1100, a memory 1300, a user interface input device 1400, a user interface output device 1500, storage 1600, and a network interface 1700 connected through a bus 1200.

The processor 1100 may be a central processing device (CPU) or a semiconductor device that processes instructions stored in the memory 1300 and/or the storage 1600. The memory 1300 and the storage 1600 may include various types of volatile or non-volatile storage media. For example, the memory 1300 may include a ROM (Read Only Memory) and a RAM (Random Access Memory).

Accordingly, the processes of the method or algorithm described in relation to embodiments of the present disclosure may be implemented directly by hardware executed by the processor 1100, a software module, or a combination thereof. The software module may reside in a storage medium (i.e., the memory 1300 and/or the storage 1600), such as a RAM, a flash memory, a ROM, an EPROM (Erasable Programmable ROM), an EEPROM (Electrically Erasable Programmable ROM), a register, a hard disk, solid state drive (SSD), a detachable disk, or a compact disk (CD)-ROM.

The storage medium is coupled to the processor 1100, and the processor 1100 may read information from the storage medium and may write information in the storage medium. In another method, the storage medium may be integrated with the processor 1100. The processor and the storage medium may reside in an application specific integrated circuit (ASIC). The ASIC may reside in a user terminal. In another method, the processor and the storage medium may reside in the user terminal as an individual component.

As an example, the computing system 1000 may be implemented to perform at least one of the functions and methods disclosed in FIGS. 1 to 10 described above, and be applied to at least one of the EV1 10 and EV2 20 and the charging/discharging system 30 described above.

The present technology provides an apparatus for diagnosing and evaluating the charge and discharge state of an electric vehicle battery, a system including the same, and a method thereof.

In addition, the present technology provides an apparatus for diagnosing and evaluating an electric vehicle battery state which is capable of diagnosing and evaluating the state of an EV battery more quickly through an EV-to-EV (electrical vehicle to electrical vehicle) power transfer system, a system including the same, and a method thereof.

In addition, the present technology provides a charging and discharging method that is capable of rapidly and accurately diagnosing and evaluating the state of a high-voltage battery of a diagnosis target vehicle by simultaneously performing EV-to-EV charging and discharging without using a separate dedicated charger and discharger, and a system therefor.

In addition, the present technology provides a battery state diagnosis and evaluation method through EV-to-EV charging/discharging, which not only increases discharge power and shortens the time required for discharging, but also minimizes energy waste by recharging the battery using the recovered energy after discharge energy recovery, and a system therefor.

In addition, the present technology may reduce the form factor by diagnosing the state of a high-voltage battery through EV-to-EV charging/discharging, so no additional installation costs are incurred and installation space is unnecessary.

In addition, the present technology may be used to evaluate high-voltage battery charge/discharge for general EVs that are not equipped with a multi-inverter.

In addition, various effects that are directly or indirectly understood through the present disclosure may be provided.

Although embodiments of the present disclosure have been described for illustrative purposes, those having ordinary skill in the art should appreciate that various modifications, additions and substitutions are possible, without departing from the scope and spirit of the disclosure.

Therefore, embodiments disclosed in the present disclosure are provided for the sake of descriptions, not limiting the technical concepts of the present disclosure, and it should be understood that such embodiments are not intended to limit the scope of the technical concepts of the present disclosure. The protection scope of the present disclosure should be understood by the claims below, and all the technical concepts within the equivalent scopes should be interpreted to be within the scope of the right of the present disclosure.

What is claimed is:

1. A system for diagnosing and evaluating a state of a battery, the system comprising:
a charging and discharging system configured to provide a direct high-voltage path for charging and discharging between a diagnosis target vehicle and a center vehicle; and
a diagnostic device configured to
obtain, from the diagnosis target vehicle through diagnostic communication, vehicle data corresponding to each of charging and discharging, and
diagnose and evaluate a state of a battery of the diagnosis target vehicle based on the vehicle data,
wherein energy discharged from a battery of the center vehicle is charged to the battery of the diagnosis target vehicle through the charging and discharging system after energy discharged from the battery of the diagnosis target vehicle is charged to the battery of the center vehicle through the charging and discharging system.

2. The system of claim 1, wherein the diagnostic device or the charging and discharging system is further configured to determine a time point at which to start a discharging and charging sequence for the battery of the diagnosis target vehicle based on a current state of charge (SOC) of the battery of the diagnosis target vehicle.

3. The system of claim 2, wherein the charging and discharging system is configured to receive information about the current SOC of the battery of the diagnosis target vehicle from the diagnostic device to determine the time point at which to start the discharging and charging sequence for the battery of the diagnosis target vehicle, and
wherein the diagnostic device is configured to obtain the information about the current SOC of the battery of the diagnosis target vehicle through the diagnostic communication from the diagnosis target vehicle.

4. The system of claim 1, wherein the vehicle data corresponding to each of the charging and discharging includes at least one of a state of charge (SOC), a maximum voltage (Vmax), or a minimum voltage (Vmin) of the battery of the diagnosis target vehicle.

5. The system of claim 4, wherein the charging and discharging system is configured to compare the vehicle data with reference values corresponding to a current state based on the current state to determine a time point at which to terminate the charging and discharging, and
wherein the current state includes a charging state and a discharging state.

6. The system of claim 5, wherein the charging and discharging system is configured to:
determine, based on that the current state is the charging state, charging termination based on the SOC being equal to or greater than a predetermined charging termination SOC upper limit or the Vmax being equal to or greater than a predetermined charging termination cell voltage upper limit and the Vmin being equal to or greater than a predetermined charging termination cell voltage lower limit; and
determine, based on that the current state is the discharging state, discharging termination based on the SOC being lower than or equal to a predetermined discharging termination SOC lower limit or the Vmin being lower than or equal to a predetermined discharging termination cell voltage lower limit.

7. The system of claim 6, wherein the current state further includes a pause state,
wherein the charging and discharging system is further configured to:
determine an initiation time point of a pause sequence based on an intensity of a current flowing in the battery of the diagnosis target vehicle; and
determine an end time point of the pause state by comparing an amount of voltage change of all cells of the battery of the diagnosis target vehicle after initiating the pause sequence with a voltage reference value corresponding to a previous state, and
wherein the previous state includes the charging state and the discharging state.

8. The system of claim 7, wherein the charging and discharging system is further configured to:
drive a pause timer upon initiation of the pause sequence; and
terminate the pause state based on expiration of the pause timer.

9. The system of claim 1, wherein the charging and discharging system includes a plurality of fast chargers, and
wherein the charging and discharging system is further configured to:
transmit a simulation signal for generating the direct high-voltage path to each of the diagnosis target vehicle and the center vehicle through power line communication based on the diagnosis target vehicle and the center vehicle being connected to different fast chargers, respectively, among the plurality of fast chargers,
close a high-voltage relay of each of the diagnosis target vehicle and the center vehicle based on the simulation signal, and
generate the direct high-voltage path between a fast charging port and a high-voltage battery.

10. The system of claim 1, wherein the diagnostic device is further configured to:
calculate a current charging and discharging depth of discharge (DOD) based on information about a battery capacity specification and a current SOC corresponding to at least one of the diagnosis target vehicle or the center vehicle obtained through the diagnostic communication, and
determine and display at least one user-selectable diagnostic option by checking whether the current charging and discharging DOD is within an available range.

11. A method of diagnosing and evaluating a state of a battery, the method comprising:
generating, by a charging and discharging system, a direct high-voltage path for charging and discharging between a diagnosis target vehicle and a center vehicle;
obtaining, by a diagnostic device and from the diagnosis target vehicle through diagnostic communication, vehicle data corresponding to each of the charging and discharging; and
diagnosing and evaluating, by the diagnostic device, a state of a battery of the diagnosis target vehicle based on the vehicle data,
wherein energy discharged from a battery of the center vehicle is charged to the battery of the diagnosis target vehicle through the charging and discharging system after energy discharged from the battery of the diagnosis target vehicle is charged to the battery of the center vehicle through the charging and discharging system.

12. The method of claim 11, further comprising:
determining, by the diagnostic device or the charging and discharging system, a time point at which to start a discharging and charging sequence for the battery of the diagnosis target vehicle based on a current state of charge (SOC) of the battery of the diagnosis target vehicle.

13. The method of claim 12, further comprising:
receiving, by the charging and discharging system, information about the current SOC of the battery of the diagnosis target vehicle from the diagnostic device to determine the time point at which to start the discharging and charging sequence for the battery of the diagnosis target vehicle, and
wherein the diagnostic device is configured to obtain the information about the current SOC of the battery of the diagnosis target vehicle through the diagnostic communication from the diagnosis target vehicle.

14. The method of claim 11, wherein the vehicle data corresponding to each of the charging and discharging includes at least one of a state of charge (SOC), a maximum voltage (Vmax), or a minimum voltage (Vmin) of the battery of the diagnosis target vehicle.

15. The method of claim 14, further comprising:
comparing, by the charging and discharging system, the vehicle data with reference values corresponding to a current state of the battery to determine a time point at which to terminate the charging and discharging, and
wherein the current state includes a charging state and a discharging state.

16. The method of claim 15, further comprising:
determining, by the charging and discharging system and based on that the current state is the charging state, charging termination based on the SOC being equal to or greater than a predetermined charging termination SOC upper limit or the Vmax being equal to or greater than a predetermined charging termination cell voltage upper limit and the Vmin being equal to or greater than a predetermined charging termination cell voltage lower limit; and
determining, by the charging and discharging system and based on that the current state is the discharging state, discharging termination based on the SOC being lower than or equal to a predetermined discharging termination SOC lower limit or the Vmin being lower than or equal to a predetermined discharging termination cell voltage lower limit.

17. The method of claim 16, wherein the current state further includes a pause state, and
wherein the method further includes:
determining, by the charging and discharging system, an initiation time point of a pause sequence based on an intensity of a current flowing in the battery of the diagnosis target vehicle; and
determining, by the charging and discharging system, an end time point of the pause state by comparing an amount of voltage change of all cells of the battery of the diagnosis target vehicle after initiating the pause sequence with a voltage reference value corresponding to a previous state, and
wherein the previous state includes the charging state and the discharging state.

18. The method of claim 17, further comprising:
driving, by the charging and discharging system, a pause timer upon initiation of the pause sequence; and
terminating, by the charging and discharging system, the pause state based on expiration of the pause timer.

19. The method of claim 11, wherein the charging and discharging system includes a plurality of fast chargers, and
the method further includes transmitting, by the charging and discharging system, a simulation signal for generating the direct high-voltage path to each of the diagnosis target vehicle and the center vehicle through power line communication based on the diagnosis target vehicle and the center vehicle being connected to different fast chargers, respectively, among the plurality of fast chargers, and
wherein high-voltage relays of the diagnosis target vehicle and the center vehicle are closed based on the simulation signal, and the direct high-voltage path is generated between a fast charging port and a high-voltage battery.

20. The method of claim 11, further comprising:
calculating, by the diagnostic device, a current charging and discharging depth of discharge (DOD) based on information about a battery capacity specification and a current SOC corresponding to at least one of the diagnosis target vehicle or the center vehicle obtained through the diagnostic communication; and
determining and displaying, by the diagnostic device, at least one user-selectable diagnostic option by checking whether the current charging and discharging DOD is within an available range.
